(19) United States
(12) Patent Application Publication
(10) Pub. No.: US 2018/0090638 A1
(43) Pub. Date: Mar. 29, 2018

(54) Graphene Liquid Crystal Display, Graphene Luminous Component, And Method for Fabricating the Same

(71) Applicant: Shenzhen China Star Optoelectronics Technology Co., Ltd., Shenzhen, Guangdong (CN)

(72) Inventor: Yong FAN, Shenzhen, Guangdong (CN)

(73) Assignee: Shenzhen China Star Optoelectronics Technology Co., Ltd., Shenzhen, Guangdong (CN)

(21) Appl. No.: 15/038,469

(22) PCT Filed: Apr. 8, 2016
(86) PCT No.: PCT/CN2016/078789

§ 371 Date: May 22, 2016

(30) Foreign Application Priority Data
Mar. 28, 2016 (CN) 201610184687.8

(51) Int. Cl. H01L 33/00; H01L 33/34; G02F 1/1335; H01L 33/44; H01L 27/15

(52) U.S. Cl. CPC H01L 33/0054; H01L 33/34; G02F 1/133621; G02F 1/133603; G02F 2001/133612; H01L 27/15; H01L 33/0041; H01L 33/0037; G02F 1/133605; H01L 33/44

(57) ABSTRACT

The present disclosure proposes a method for fabricating a graphene luminous component. The method includes: supplying a bottom substrate on which metallic gates are arranged at intervals; forming a first insulating protective layer covering the bottom substrate and the metallic gate; forming a graphene luminous layer with graphene luminous blocks on the first insulating protective layer; forming a graphene source and a graphene drain arranged at intervals on each of graphene luminous blocks; forming a second insulating protective layer covering the first insulating protective layer, the graphene luminous layer, the graphene source, and the graphene drain; and laminating a top substrate onto the second insulating protective layer. The present disclosure proposes a gate fabricated from metal, a source, a drain, and a luminous layer fabricated from graphene for the graphene luminous component. Therefore, the luminous efficiency of the luminous component is enhanced with lower power consumption.

### BACKGROUND OF THE INVENTION

### 1. Field of the Invention

The present invention relates to the field of liquid crystal display, and more particularly, to a graphene liquid crystal display (LCD), a graphene luminous component, and a method for fabricating the graphene LCD and the graphene luminous component.

### 2. Description of the Prior Art

Liquid crystal displays (LCDs) are widely used known for features such as slimness, low power consumption, and no radiation. Liquid crystal television sets, mobile phones, personal digital assistants (PDAs), digital cameras, computer monitors, and notebook computer monitors are known as one kind of LCD.

Most conventional LCDs are backlight LCDs. A conventional LCD comprises a case, a liquid crystal panel placed in the case, and a backlight module placed in the case. The liquid crystal panel does not send out light; instead, the backlight module supplies the liquid crystal panel with light sources for showing images normally. The conventional backlight module comprises a backlight source, a light guide plate (LGP), an emission sheet, and an optical film. However, because of low luminous efficiency and high power consumption, the conventional backlight module can hardly fulfill the demand of the LCDs for further development.

### SUMMARY OF THE INVENTION

An object of the present invention is to propose a graphene LCD, a graphene luminous component, and a method for fabricating the graphene LCD and the graphene luminous component to improve and modify a conventional backlight module with lower luminous efficiency and higher power consumption.

According to the present invention, a method of fabricating a graphene luminous component comprises: supplying a bottom substrate on which a plurality of metallic gates are arranged at intervals; forming a first insulating protective layer covering the bottom substrate and the metallic gate; forming a graphene luminous layer which comprises a plurality of graphene luminous blocks arranged at intervals on the first insulating protective layer; forming a graphene source and a graphene drain arranged at intervals on each of the plurality of graphene luminous blocks; forming a second insulating protective layer covering the first insulating protective layer, the graphene luminous layer, the graphene source, and the graphene drain; and laminating a top substrate onto the second insulating protective layer.

Furthermore, the step of forming a plurality of metallic gates arranged at intervals on the bottom substrate comprises steps of: forming a metallic gate coating film on the bottom substrate by means of sputtering or evaporation; photoetching the metallic gate coating film for forming the plurality of metallic gates arranged at intervals.

Furthermore, the step of forming a graphene luminous layer on the first insulating protective layer comprises steps of: forming a first graphene thin film layer on the first insulating protective layer by means of printing, ink-jet printing, or coating; drying the first graphene thin film layer for solidifying the first graphene thin film layer; etching the solidified first graphene thin film layer with ion or laser for forming the graphene luminous layer.

Furthermore, the step of forming a graphene source and a graphene drain arranged at intervals on each of the plurality of graphene luminous blocks comprises steps of: forming a second graphene thin film layer on the graphene luminous layer by means of printing, ink-jet printing, or coating; drying the second graphene thin film layer for solidifying the second graphene thin film layer; etching the solidified second graphene thin film layer with ion or laser for forming the graphene source and the graphene drain arranged at intervals on each of the plurality of graphene luminous blocks.

Furthermore, the metallic gate is fabricated from high reflectance metals, the graphene source and the graphene drain fabricated from reduced graphene oxide, and the graphene luminous layer is fabricated from semi-reduced graphene oxide.

Furthermore, the bottom substrate and the top substrate are water- and oxygen-proof substrates with a water/oxygen permeability smaller than 10⁻⁴.

According to the present invention, a graphene luminous component comprises a bottom substrate, a plurality of metallic gates, a first insulating protective layer, a graphene luminous layer, a plurality of graphene sources, a plurality of graphene drains, a second insulating protective layer, and a top substrate from bottom to top. The plurality of metallic gates are arranged at intervals on the bottom substrate. The first insulating protective layer covers the bottom substrate and the metallic gate. The graphene luminous layer are arranged on the first insulating protective layer, and a plurality of graphene luminous blocks are arranged at intervals on the graphene luminous layer. The graphene source and the graphene drain are arranged at intervals on each of the plurality of graphene luminous blocks. The second insulating protective layer covers the first insulating protective layer, the graphene source, the graphene luminous block, and the graphene drain. The top substrate covers the second insulating protective layer.

Furthermore, the metallic gate is fabricated from high reflectance metals, the graphene source and the graphene drain fabricated from reduced graphene oxide, and the graphene luminous layer is fabricated from semi-reduced graphene oxide.

Furthermore, the bottom substrate and the top substrate are water- and oxygen-proof substrates with a water/oxygen permeability smaller than 10⁻⁴.

According to the present invention, a graphene liquid crystal display comprises a graphene luminous component. The graphene luminous component comprises a bottom substrate, a plurality of metallic gates, a first insulating protective layer, a graphene luminous layer, a plurality of graphene sources, a plurality of graphene drains, a second insulating protective layer, and a top substrate from bottom to top. The plurality of metallic gates are arranged at intervals on the bottom substrate. The first insulating protective layer covers the bottom substrate and the metallic gate. The graphene luminous layer are arranged on the first insulating protective layer, and a plurality of graphene luminous blocks are arranged at intervals on the graphene luminous layer. The graphene source and the graphene drain are arranged at intervals on each of the plurality of graphene luminous blocks. The second insulating protective layer covers the first insulating protective layer, the graphene source, the graphene luminous block, and the graphene drain. The top substrate covers the second insulating protective layer.

Furthermore, the metallic gate is fabricated from high reflectance metals, the graphene source and the graphene drain fabricated from reduced graphene oxide, and the graphene luminous layer is fabricated from semi-reduced graphene oxide.

Furthermore, the bottom substrate and the top substrate are water- and oxygen-proof substrates with a water/oxygen permeability smaller than 10⁻⁴.

In the present invention, a gate is fabricated from metal, a source is fabricated from graphene, a drain is fabricated from graphene, and a luminous layer is fabricated from graphene for the graphene luminous component. Therefore, the luminous efficiency of the luminous component is enhanced with lower power consumption. These are the beneficiary effects provided by the present invention.

### BRIEF DESCRIPTION OF THE DRAWINGS

FIG. 1 is a flowchart of a method for fabricating a graphene luminous component according to one preferred embodiment of the present invention.

FIG. 2A˜FIG. 2E are schematic diagrams of the graphene luminous component in the producing process with the method as shown in FIG. 1.

FIG. 3 is a schematic diagram of the graphene luminous component with the method as shown in FIG. 1.

FIG. 4 is a schematic diagram of a graphene liquid crystal display according to the present invention.

### DETAILED DESCRIPTION OF THE PREFERRED EMBODIMENTS

The accompanying drawings are included to provide a further understanding of the invention, and are incorporated in and constitute a part of this specification. The drawings illustrate embodiments of the invention and, together with the description, serve to explain the principles of the invention.

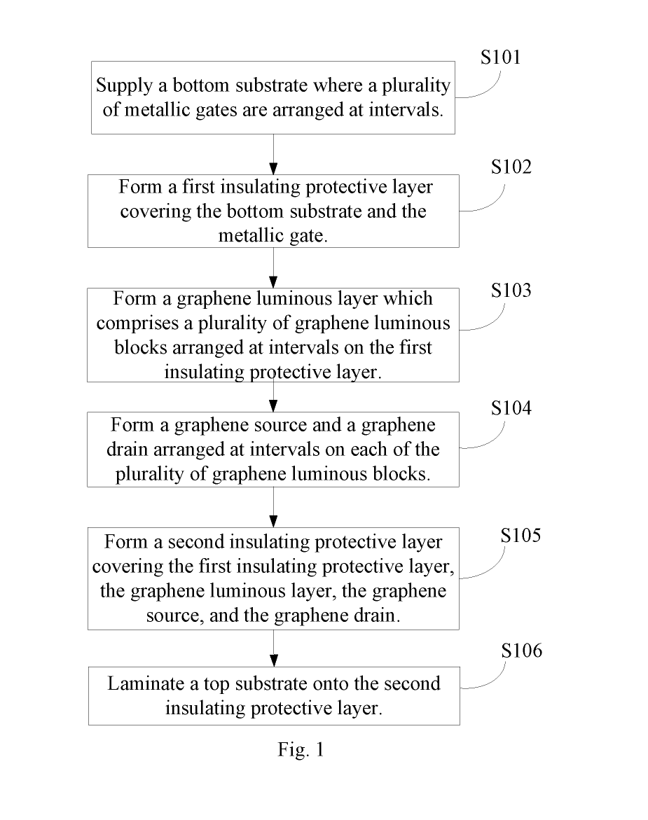

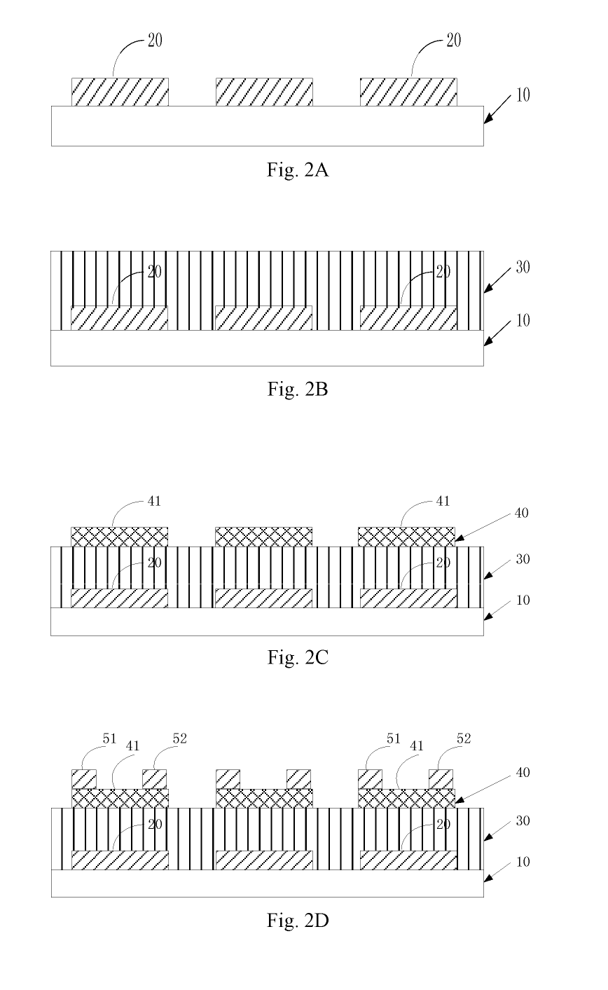

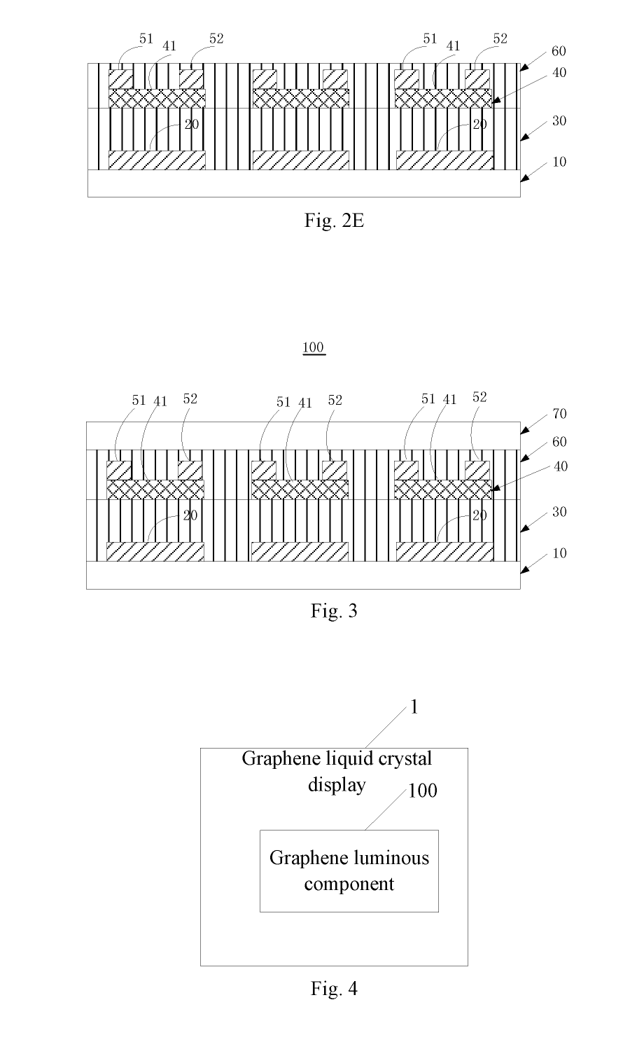

FIG. 1 is a flowchart of a method for fabricating a graphene luminous component 100 according to one preferred embodiment of the present invention. FIG. 2A˜FIG. 2E are schematic diagrams of the graphene luminous component 100 in the producing process with the method as shown in FIG. 1. It is notified that the processes listed on FIG. 1 are not limited if the results are the same. The method comprises steps of:

Step S101: Supply a bottom substrate where a plurality of metallic gates are arranged at intervals.

The step S101 of supplying a bottom substrate where a plurality of metallic gates are arranged at intervals comprises steps of forming a metallic gate coating film on the bottom substrate 10 by means of sputtering or evaporation, and photoetching the metallic gate coating film for forming the plurality of metallic gates arranged at intervals.

The bottom substrate 10 is fabricated from water- and oxygen-proof transparent organic material (such as polyethylene terephthalate, PET), glass, or nickel (Ni). The bottom substrate 10 is a water- and oxygen-proof substrate with a water/oxygen permeability smaller than 10⁻⁴ in this embodiment. It is good for enhancing the water- and oxygen-proof ability of the graphene luminous component 100.

Preferably, the metallic gate is fabricated from high reflectance metals, such as aluminum (Al), silver (Ag), and an alloy of aluminum and silver, for further enhancing the luminous efficiency of the graphene luminous component 100.

Please refer to FIG. 2A as well. FIG. 2A is a cross-sectional view of a bottom substrate 10 for forming the metallic gate 20. The plurality of metallic gates 20 are arranged on the bottom substrate 10 at intervals.

Step S102: Form a first insulating protective layer covering the bottom substrate and the metallic gate.

The Step S102 of forming a first insulating protective layer 30 covering the bottom substrate 10 and the metallic gate 20 comprises steps of depositing the first insulating protective layer 30 on the bottom substrate 10 and the metallic gate 20 by means of chemical vapor deposition (CVD), and covering the bottom substrate 10 and the metallic gate 20 with the first insulating protective layer 30.

Preferably, the first insulating protective layer 30 is fabricated from silicon nitride (SiNX). Please refer to FIG. 2B as well. FIG. 2B is a cross-sectional view of forming the bottom substrate 10 with the first insulating protective layer 30. The first insulating protective layer 30 covers the bottom substrate 10 and the metallic gate 20.

Step S103: Form a graphene luminous layer which comprises a plurality of graphene luminous blocks arranged at intervals on the first insulating protective layer.

The Step S103 of forming a graphene luminous layer 40 on the first insulating protective layer 30 comprises steps of forming a first graphene thin film layer on the first insulating protective layer 30 by means of printing, ink-jet printing, or coating, drying the first graphene thin film layer for solidifying the first graphene thin film layer, and etching the solidified first graphene thin film layer with ion or laser for forming the graphene luminous layer 40.

Preferably, the graphene luminous layer 40 is fabricated from the semi-reduced graphene oxide. The semi-reduced graphene oxide is fabricated and prepared with the hummer's method, which adopting solution reaction, so the graphene luminous layer 40 can be fabricated and prepared by means of printing, ink-jet printing, or coating.

Please refer FIG. 2C as well. FIG. 2C is a cross-sectional view of forming the bottom substrate 10 with the graphene luminous layer 40. The graphene luminous layer 40 is arranged on the first insulating protective layer 30. The graphene luminous layer 40 comprises a plurality of graphene luminous blocks 41 arranged at intervals. The graphene luminous block 41 and the metallic gate 20 are arranged one on one. Preferably, the width of the graphene luminous block 41 is the same as the width of the metallic gate 20. In other words, the graphene luminous block 41 is installed on the metallic gate 20.

The second insulating protective layer 60 covers the first insulating protective layer 30, the graphene luminous layer 40, the graphene source 51, and the graphene drain 52.

Step S104: Form a graphene source and a graphene drain arranged at intervals on each of the plurality of graphene luminous blocks.

The Step S104 of forming a graphene source and a graphene drain arranged at intervals on each of the plurality of graphene luminous blocks comprises steps of forming a second graphene thin film layer on the graphene luminous layer 40 by means of printing, ink-jet printing, or coating, drying the second graphene thin film layer for solidifying the second graphene thin film layer, and etching the solidified second graphene thin film layer with ion or laser for forming the graphene source 51 and the graphene drain 52 arranged at intervals on each of the plurality of graphene luminous blocks 41.

Preferably, the graphene source 51 and the graphene drain 52 are fabricated from the reduced graphene oxide. The reduced graphene oxide is fabricated and prepared with the hummer's method, which adopting solution reaction, so the graphene source 51 and the graphene drain 52 can be fabricated and prepared by means of printing, ink-jet printing, or coating.

Please refer to FIG. 2D as well. FIG. 2D is a cross-sectional view of forming the bottom substrate 10 comprising the graphene source 51 and the graphene drain 52. The graphene source 51 and the graphene drain 52 are arranged on the graphene luminous layer 40 alternatively. The graphene source 51 and the graphene drain 52 as a pair are arranged on each of the plurality of graphene luminous blocks 41.

Step S105: Form a second insulating protective layer covering the first insulating protective layer, the graphene luminous layer, the graphene source, and the graphene drain.

The Step S105 of forming a second insulating protective layer 60 covering the insulating protective layer, the graphene luminous layer 40, the graphene source 51, and the graphene drain 52 comprises steps of depositing the second insulating protective layer 60 on the first insulating protective layer 30, the graphene luminous layer 40, the graphene source 51, and the graphene drain 52 by means of chemical vapor deposition (CVD), and covering the first insulating protective layer 30, the graphene luminous layer 40, the graphene source 51, and the graphene drain 52 with the second insulating protective layer 60.

Preferably, the second insulating protective layer 60 is fabricated from silicon nitride (SiN_{X}).

Please refer to FIG. 2E as well. FIG. 2E is a cross-sectional view of forming the bottom substrate 10 with the second insulating protective layer 60. The second insulating protective layer 60 covers the first insulating protective layer 30, the graphene luminous layer 40, the graphene source 51, and the graphene drain 52.

The second insulating protective layer 60 and the first insulating protective layer 30 are fabricated from the same material in this embodiment. It is probable that the second insulating protective layer 60 and the first insulating protective layer 30 are fabricated from different materials in another embodiment.

Step S106: Laminate a top substrate onto the second insulating protective layer.

In Step S106, the top substrate 70 is fabricated from water- and oxygen-proof transparent organic material (such as polyethylene terephthalate, PET) or glass. Preferably, the top substrate 70 is a water- and oxygen-proof substrate with a water/oxygen permeability smaller than 10⁻⁴ in this embodiment. It is good for enhancing the water- and oxygen-proof ability of the graphene luminous component 100.

The graphene luminous component 100 is produced after the top substrate 70 is laminated on the second insulating protective layer 60.

Please refer to FIG. 3. FIG. 3 is a schematic diagram of the graphene luminous component 100 with the method as shown in FIG. 1. The graphene luminous component 100 comprises the bottom substrate 10, the plurality of metallic gates 20, the first insulating protective layer 30, the graphene luminous layer 40, the plurality of graphene sources 51, the plurality of graphene drains 52, the second insulating protective layer 60, and the top substrate 70 from bottom to top.

The plurality metallic gates 20 are arranged on the bottom substrate 10 at intervals. Preferably, the plurality metallic gates 20 are fabricated from high reflectance metals, such as aluminum (Al), silver (Ag), and an alloy of aluminum and silver, for further enhancing the luminous efficiency of the graphene luminous component 100.

The first insulating protective layer 30 covers the bottom substrate 10 and the metallic gate 20. Preferably, the first insulating protective layer 30 is fabricated from silicon nitride (SiNX).

The graphene luminous layer 40 is arranged on the first insulating protective layer 30. The graphene luminous layer 40 comprises a plurality of graphene luminous blocks 41. Preferably, the graphene luminous layer 40 is fabricated from the semi-reduced graphene oxide.

The graphene source 51 and the graphene drain 52 are arranged on the graphene luminous block 41 at intervals. Preferably, the graphene source 51 and the graphene drain 52 are fabricated from the reduced graphene oxide.

The second insulating protective layer 60 covers the first insulating protective layer 30, the graphene source 51, the graphene luminous block 41, and the graphene drain 52. Preferably, the second insulating protective layer 60 is fabricated from silicon nitride (SiNX).

The top substrate 70 covers the second insulating protective layer 60. Preferably, the bottom substrate 10 and the top substrate 70 are water- and oxygen-proof substrate with a water/oxygen permeability smaller than 10⁻⁴. It is good for enhancing the water- and oxygen-proof ability of the graphene luminous component 100.

Graphene, known as two-dimensional (2D) materials, has characteristics of semiconductor and conductor. Specifically, graphene possess features of stiff texture, high transparency (the rate of penetration≈97.7%), high heat transfer coefficient (up to 5300 W/m·K), high electron mobility (over 15000 cm2/V·s), etc., so graphene can be a material for a source, a drain, a luminous layer. Therefore, the graphene luminous component 100 possesses features of high luminous efficiency and low power consumption.

As for the emitting principle of the graphene luminous component 100, the details are as follows: The electric field generated by the voltage imposed on the metallic gate 20 adjusts the Fermi level of the graphene luminous block 41, thereby adjusting the wavelength of the graphene luminous block 41, so that the graphene luminous block 41 can emit light with diverse colors.

Specifically, take the graphene luminous block 41 as semi-reduced graphene oxide for example. The graphene luminous block 41 emits the red light when the voltage difference (Vgs) between the metallic gate 20 and the graphene source 51 is between the zero volt and ten volts (0 V˜10 V), and the voltage difference (Vds) between the graphene source 51 and the graphene drain 52 is larger than the threshold voltage (Vth). The graphene luminous block 41 emits the green light when the voltage difference (Vgs) between the metallic gate 20 and the graphene source 51 is between the twenty volts and thirty volts (20 V˜30 V), and the voltage difference (Vds) between the graphene source 51 and the graphene drain 52 is larger than the threshold voltage (Vth). The graphene luminous block 41 emits the blue light when the voltage difference (Vgs) between the metallic gate 20 and the graphene source 51 is between the forty volts and fifty volts (40 V˜50 V), and the voltage difference (Vds) between the graphene source 51 and the graphene drain 52 is larger than the threshold voltage (Vth).

In addition, the strength of the red light, the green light, or the blue light emitted by the graphene luminous block 41 changes with the voltage difference (Vds) between the graphene source 51 and the graphene drain 52 for further adjusting grayscale.

Please refer to FIG. 4. FIG. 4 is a schematic diagram of a graphene liquid crystal display 1 according to the present invention. As FIG. 4 shows, the graphene liquid crystal display 1 comprises the graphene luminous component 100.

The present invention provides the beneficiary effects as follows: The graphene luminous component comprises a gate fabricated from high reflectance metals, a source and a drain fabricated from the reduced graphene oxide, and a graphene luminous layer 40 fabricated from the semi-reduced graphene oxide. The luminous efficiency of the luminous component is enhanced with lower power consumption. Also, the graphene luminous component comprises a top substrate and a bottom substrate which are both water- and oxygen-proof substrates. It is good for improving the water- and oxygen-proof ability of the graphene luminous component. Besides, the graphene luminous component does not comprise an LGP and an optical film which are necessary for the conventional technology. The material costs for producing an LCD are reduced accordingly. The LCD becomes lighter and thinner as well.

Although the present invention has been explained by the embodiments shown in the drawings described above, it should be understood to the ordinary skilled person in the art that the invention is not limited to the embodiments, but rather various changes or modifications thereof are possible without departing from the spirit of the invention. Accordingly, the scope of the invention shall be determined only by the appended claims and their equivalents.

What is claimed is:

1. A method of fabricating a graphene luminous component, comprising:
supplying a bottom substrate on which a plurality of metallic gates are arranged at intervals;
forming a first insulating protective layer covering the bottom substrate and the metallic gate;
forming a graphene luminous layer which comprises a plurality of graphene luminous blocks arranged at intervals on the first insulating protective layer;
forming a graphene source and a graphene drain arranged at intervals on each of the plurality of graphene luminous blocks;
forming a second insulating protective layer covering the first insulating protective layer, the graphene luminous layer, the graphene source, and the graphene drain; and
laminating a top substrate onto the second insulating protective layer.

2. The method of claim 1, wherein the step of forming a plurality of metallic gates arranged at intervals on the bottom substrate comprises steps of:
forming a metallic gate coating film on the bottom substrate by means of sputtering or evaporation;
photoetching the metallic gate coating film for forming the plurality of metallic gates arranged at intervals.

3. The method of claim 1, wherein the step of forming a graphene luminous layer on the first insulating protective layer comprises steps of:
forming a first graphene thin film layer on the first insulating protective layer by means of printing, ink-jet printing, or coating;
drying the first graphene thin film layer for solidifying the first graphene thin film layer;
etching the solidified first graphene thin film layer with ion or laser for forming the graphene luminous layer.

4. The method of claim 1, wherein the step of forming a graphene source and a graphene drain arranged at intervals on each of the plurality of graphene luminous blocks comprises steps of:
forming a second graphene thin film layer on the graphene luminous layer by means of printing, ink-jet printing, or coating;
drying the second graphene thin film layer for solidifying the second graphene thin film layer;
etching the solidified second graphene thin film layer with ion or laser for forming the graphene source and the graphene drain arranged at intervals on each of the plurality of graphene luminous blocks.

5. The method of claim 1, wherein the metallic gate is fabricated from high reflectance metals, the graphene source and the graphene drain fabricated from reduced graphene oxide, and the graphene luminous layer is fabricated from semi-reduced graphene oxide.

6. The method of claim 1, wherein the bottom substrate and the top substrate are water- and oxygen-proof substrates with a water/oxygen permeability smaller than 10⁻⁴.

7. A graphene luminous component, comprising a bottom substrate, a plurality of metallic gates, a first insulating protective layer, a graphene luminous layer, a plurality of graphene sources, a plurality of graphene drains, a second insulating protective layer, and a top substrate from bottom to top;
wherein the plurality of metallic gates are arranged at intervals on the bottom substrate;
wherein the first insulating protective layer covers the bottom substrate and the metallic gate;
wherein the graphene luminous layer are arranged on the first insulating protective layer, and a plurality of graphene luminous blocks are arranged at intervals on the graphene luminous layer;
wherein the graphene source and the graphene drain are arranged at intervals on each of the plurality of graphene luminous blocks;
wherein the second insulating protective layer covers the first insulating protective layer, the graphene source, the graphene luminous block, and the graphene drain; and
wherein the top substrate covers the second insulating protective layer.

8. The graphene luminous component of claim 7, wherein the metallic gate is fabricated from high reflectance metals, the graphene source and the graphene drain fabricated from reduced graphene oxide, and the graphene luminous layer is fabricated from semi-reduced graphene oxide.

9. The graphene luminous component of claim 7, wherein the bottom substrate and the top substrate are water- and oxygen-proof substrates with a water/oxygen permeability smaller than 10⁻⁴.

10. A graphene liquid crystal display comprising a graphene luminous component, the graphene luminous component comprising a bottom substrate, a plurality of metallic gates, a first insulating protective layer, a graphene luminous layer, a plurality of graphene sources, a plurality of graphene drains, a second insulating protective layer, and a top substrate from bottom to top;
wherein the plurality of metallic gates are arranged at intervals on the bottom substrate;
wherein the first insulating protective layer covers the bottom substrate and the metallic gate;
wherein the graphene luminous layer are arranged on the first insulating protective layer, and a plurality of graphene luminous blocks are arranged at intervals on the graphene luminous layer;
wherein the graphene source and the graphene drain are arranged at intervals on each of the plurality of graphene luminous blocks;
wherein the second insulating protective layer covers the first insulating protective layer, the graphene source, the graphene luminous block, and the graphene drain; and
wherein the top substrate covers the second insulating protective layer.

11. The graphene liquid crystal display of claim 10, wherein the metallic gate is fabricated from high reflectance metals, the graphene source and the graphene drain fabricated from reduced graphene oxide, and the graphene luminous layer is fabricated from semi-reduced graphene oxide.

12. The graphene liquid crystal display of claim 10, wherein the bottom substrate and the top substrate are water- and oxygen-proof substrates with a water/oxygen permeability smaller than 10⁻⁴.
